(19) United States
(12) Patent Application Publication
(10) Pub. No.: US 2025/0006513 A1
(43) Pub. Date: Jan. 2, 2025

(54) SUBSTRATE PROCESSING APPARATUS AND SUBSTRATE PROCESSING METHOD

(71) Applicant: SEMES CO., LTD., Cheonan-si (KR)

(72) Inventors: Yong Hee LEE, Cheonan-si (KR); Tae Jong CHOI, Cheonan-si (KR); Mi So PARK, Asan-si (KR)

(73) Assignee: SEMES CO., LTD., Cheonan-si (KR)

(21) Appl. No.: 18/676,894

(22) Filed: May 29, 2024

(30) Foreign Application Priority Data
Jun. 28, 2023 (KR) 10-2023-0083383

(51) Int. Cl. H01L 21/67

(52) U.S. Cl. CPC H01L 21/67017

(57) ABSTRACT

Disclosed is an apparatus for processing a substrate, the apparatus including: a body providing a processing space; a first fluid supply line connected to the body and supplying treatment fluid to the processing space; a second fluid supply line connected to the body at a location different from the first fluid supply line and supplying treatment fluid to the processing space; a first supply valve installed in the first fluid supply line; and an air removal line having one end connected to the first fluid supply line in a lower stream than the first supply valve to allow air in the processing space that is introduced into the first fluid supply line to be removed from the first fluid supply line when the second fluid supply line supplies treatment fluid to the processing space.

### CROSS-REFERENCE TO RELATED APPLICATIONS

This application claims priority to and the benefit of Korean Patent Application No. 10-2023-0083383 filed in the Korean Intellectual Property Office on Jun. 28, 2023 the entire contents of which are incorporated herein by reference.

### TECHNICAL FIELD

The present invention relates to a substrate processing apparatus and a substrate processing method.

### BACKGROUND ART

To manufacture a semiconductor device, a desired pattern is formed on a substrate, such as a wafer, through various processes, such as photography, etching, ashing, ion implantation, and thin film deposition. Various processing solutions and processing gas are used in each process, and particles and process by-products are generated during the process. Cleaning processes are performed before and after each process to remove these particles and process by-products from the substrate.

In the cleaning process, the substrate is cleaned by supplying a cleaning solution to the substrate. The substrate is then dried to remove any residual cleaning solution on the substrate. One example of a drying treatment is a rotary drying process in which the substrate is rotated at a high speed to remove any residual cleaning solution on the substrate. However, the rotary drying process that rotates the substrate to remove the cleaning solution has the risk of destroying the pattern formed on the substrate. In addition, as the aspect ratio of the patterns increases, the cleaning fluid introduced between the patterns may not be adequately removed due to the rotation of the substrate.

Recently, a supercritical drying process has been utilized in which the residual cleaning solution on the substrate is replaced with an organic solvent, such as isopropyl alcohol (IPA), which has a low surface tension, and the substrate is then supplied with supercritical drying gas (for example, carbon dioxide) to remove the residual organic solvent from the substrate. In a supercritical drying process, drying gas is supplied into a sealed chamber, and the drying gas is heated and pressurized. Both the temperature and the pressure of the drying gas rise to the critical point or above, and the drying gas undergoes a phase change to the supercritical state.

The drying gas in the supercritical state has high solubility and permeability. In other words, when supercritical drying gas is supplied to the substrate, the drying gas easily penetrates into the patterns on the substrate, and the organic solvent remaining on the substrate is also easily dissolved in the drying gas. Thus, the patterns formed on the substrate and the organic solvent remaining between the patterns may be easily removed.

FIG. 1 is a diagram illustrating a general substrate processing apparatus performing a supercritical drying process.

Referring to FIG. 1, a substrate processing apparatus performing a typical supercritical drying process includes a lower chamber 1, an upper chamber 2, a support member 3, a lower supply line 4, a lower valve 5, an upper supply line 6, an upper valve 7, an exhaust valve 8, and a pump 9.

The lower chamber 1 and the upper chamber 2 are combined with each other to provide a processing space in which the substrate W is processed, and a support member 3 is installed in the upper chamber 2 and configured to support the bottom edge region of the substrate W. When the process is started, the lower supply line 4 supplies drying gas G to the lower portion of the substrate W. The drying gas G increases the pressure in the processing space. The pressure in the processing space provided by the chambers 1 and 2 is pressurized above a critical pressure at which the drying gas G may maintain a supercritical state.

The drying gas G may not be able to maintain the supercritical state until the pressure in the processing space reaches the threshold pressure. For this reason, supplying the drying gas G from the upper supply line 6 first may cause the substrate W to be supplied with the drying gas G in a gaseous state that is not a supercritical state. Therefore, when the processing space is pressurized, the drying gas G is first supplied from the lower supply line 4, and when the pressure of the processing space is somewhat increased, the drying gas G is supplied from the upper supply line 6.

In this case, the drying gas G supplied through the lower supply line 4 pushes the air in the processing space in an upward direction. The air pushed by the drying gas G is introduced into the upper supply line 6 and is compressed in the vicinity of the closed upper valve 7. The compressed air forms an air pocket AP.

The air pocket AP is transferred to the top surface of the substrate W when the supply of the drying gas G from the upper supply line 6 starts, as illustrated in FIG. 2. The air pocket AP transferred to the substrate W are likely to cause defects in the substrate W.

### SUMMARY OF THE INVENTION

The present invention has been made in an effort to provide a substrate processing apparatus and a substrate processing method, which are capable of efficiently processing a substrate.

The present invention has been made in an effort to provide a substrate processing apparatus and a substrate processing method, which are capable of increasing efficiency of drying treatment for a substrate.

The present invention has been made in an effort to provide a substrate processing apparatus and a substrate processing method, which are capable of minimizing the transfer of an air pocket to a substrate.

The object of the present invention is not limited thereto, and other objects not mentioned will be clearly understood by those of ordinary skill in the art from the following description.

An exemplary embodiment of the present invention provides an apparatus for processing a substrate, the apparatus including: a body providing a processing space; a first fluid supply line connected to the body and supplying treatment fluid to the processing space; a second fluid supply line connected to the body at a location different from the first fluid supply line and supplying treatment fluid to the processing space; a first supply valve installed in the first fluid supply line; and an air removal line having one end connected to the first fluid supply line in a lower stream than the first supply valve to allow air in the processing space that is introduced into the first fluid supply line to be removed from the first fluid supply line when the second fluid supply line supplies treatment fluid to the processing space.

According to the exemplary embodiment, the apparatus may further include an exhaust line for exhausting atmosphere of the processing space, in which the other end of the air removal line may be connected to the exhaust line.

According to the exemplary embodiment, the apparatus may further include an exhaust line installed in the exhaust line, in which to allow air introduced into the air removal line to be discharged from the processing space, the other end of the air removal line may be connected to the exhaust line in a lower stream than the exhaust valve.

According to the exemplary embodiment, the apparatus may further include an exhaust line installed in the exhaust line, in which to allow air introduced into the air removal line to be circulated to the processing space, the other end of the air removal line may be connected to the exhaust line in an upper stream than the exhaust valve.

According to the exemplary embodiment, the apparatus may further include an exhaust line installed in the exhaust line, in which air removal line may include: a main removal line connected with the first fluid supply line; a circulation line branched from the main removal line and connected to an upper stream than the exhaust valve; and discharge line branched from the main removal line to be connected to a lower stream than the exhaust valve.

According to the exemplary embodiment, the air removal line may be connected to the first fluid supply line within 200 mm from the first supply valve.

According to the exemplary embodiment, the body may be provided with a first supply port connected with the first fluid supply line, and a second supply port connected with the second fluid supply line, and an outlet of the first supply port and an outlet of the second supply port may face each other.

According to the exemplary embodiment, the apparatus may further include: an air removal valve installed in the air removal line; a second supply valve installed in the second fluid supply line; and a controller configured to controlan operation of the first supply valve, the second supply valve, and the air removal valve, in which the controller may generate signals for performing: an operation of closing the first supply valve and opening the second supply valve to allow the treatment fluid to be supplied to the processing space through the second fluid supply line; and an operation of opening the air removal valve to allow air in the processing space that is introduced into the first fluid supply line to be introduced into the air removal line.

According to the exemplary embodiment, the controller may generate a control signal to perform an operation of opening the first supply valve to allow the treatment fluid to be supplied to the processing space through the first fluid supply line after air is introduced into the air removal line.

Another exemplary embodiment of the present invention provides a method of processing a substrate, the method including: a liquid treating operation of supplying a treatment solution to the substrate; and a drying operation of loading the substrate supplied with the treatment solution into a processing space provided by a body and drying the substrate by supplying treatment fluid, in which the drying operation includes: a pressurization operation of supplying the treatment fluid to the processing space to pressurize the processing space to a set pressure; a flowing operation of flowing the treatment fluid in the processing space to remove the treatment solution remaining on the substrate; and a depressurization operation of exhausting atmosphere of the processing space to depressurize the processing space, and the pressurization operation includes: a first supply operation of supplying the treatment fluid to the processing space through a second fluid supply line connected to the body; and an air removal operation of removing air introduced from the processing space by the treatment fluid supplied in the first supply operation into a first fluid supply line—the first fluid supply line being connected to the body at a different location from the second fluid supply line-through an air removal line connected to the first fluid supply line.

According to the exemplary embodiment, the pressurization operation may further include, after the air removal operation, a second supply operation of supplying the treatment fluid to the processing space through the first fluid supply line.

According to the exemplary embodiment, the air removal line may be connected to an exhaust line for exhausting atmosphere of the processing space, and the air removal operation may include circulating the air introduced into the first fluid supply line to the processing space through the air removal line and the exhaust line.

According to the exemplary embodiment, the air removal line may be connected to an exhaust line for exhausting atmosphere of the processing space, and the air removal operation may include discharging the air introduced into the first fluid supply line from the processing space through air removal line and the exhaust line.

According to the exemplary embodiment, the air removal line may be connected to an exhaust line for exhausting atmosphere of the processing space, and the air removal operation may include discharging the air introduced into the first fluid supply line to the outside through the air removal line and the exhaust line, and then circulating the treatment fluid to the processing space through the air removal line and the exhaust line.

According to the exemplary embodiment, the air removal line may be connected to the first fluid supply line in a lower stream than a first supply valve installed in the first fluid supply line to introduce air that is to be concentrated in a region adjacent to the first supply valve into the air removal line.

According to the exemplary embodiment, the air removal line may be connected to the first fluid supply line within 200 mm from the first supply valve.

According to the exemplary embodiment, the air removal line may be connected to the first fluid supply line within 200 mm from the first supply valve.

Still another exemplary embodiment of the present invention provides an apparatus for processing a substrate, the apparatus including: a body providing a processing space; a fluid supply unit for supplying treatment fluid to the processing space; an exhaust unit for exhausting atmosphere of the processing space; and an air removal line for removing air introduced into the fluid supply unit, in which the fluid supply unit includes: a first fluid supply line for supplying treatment fluid to a first region of the processing space; a second fluid supply line for supplying treatment fluid to a second region that is different from the first region of the processing space; a first supply valve installed in the first fluid supply line; and a second supply valve installed in the second fluid supply line, and the exhaust unit may include: an exhaust line connected to the body; an exhaust valve installed on the exhaust line; and an exhaust device for exhausting atmosphere of the processing space through the exhaust line, and the air removal line has one end that is connected to the first fluid supply line at a location within 200 mm from the first supply valve and the other end connected to the exhaust line.

According to the exemplary embodiment, the apparatus may further include: an air removal valve installed in the air removal line; and a controller configured to controlan operation of the first supply valve, the second supply valve, and the air removal valve, in which the controller generates signals for performing: an operation of closing the first supply valve and opening the second supply valve to allow the treatment fluid to be supplied to the processing space through the second fluid supply line; and an operation of opening the air removal valve to allow air in the processing space that is introduced into the first fluid supply line to be introduced into the air removal line.

According to the exemplary embodiment, the controller may generate a control signal to perform an operation of opening the first supply valve to allow the treatment fluid to be supplied to the processing space through the first fluid supply line after air is introduced into the air removal line.

According to the exemplary embodiment of the present invention, it is possible to efficiently process a substrate.

Further, according to the exemplary embodiment of the present invention, the drying treatment efficiency for the substrate may be increased.

Furthermore, according to the exemplary embodiment of the present invention, it is possible to minimize transferring of air pockets to the substrate.

The effect of the present invention is not limited to the foregoing effects, and those skilled in the art may clearly understand non-mentioned effects from the present specification and the accompanying drawings.

### BRIEF DESCRIPTION OF THE DRAWINGS

FIG. 1 is a diagram illustrating a general substrate processing apparatus performing a supercritical drying process.

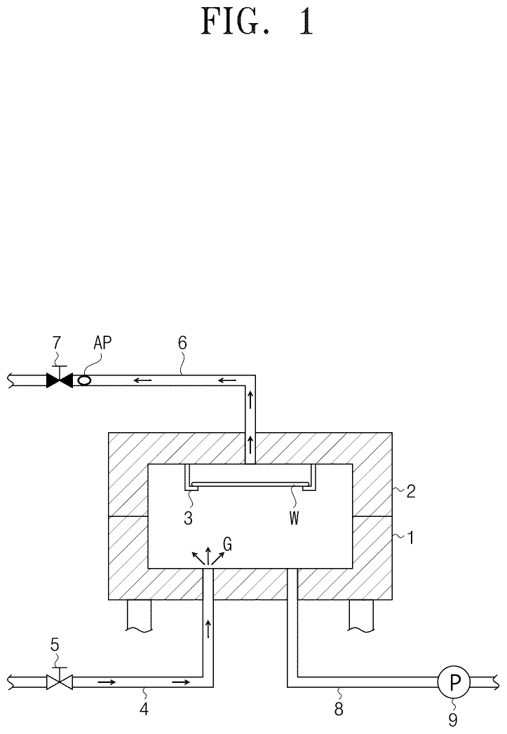

FIG. 2 is a diagram illustrating an air pocket created in a supercritical fluid supply line of FIG. 1 being transferred to a substrate.

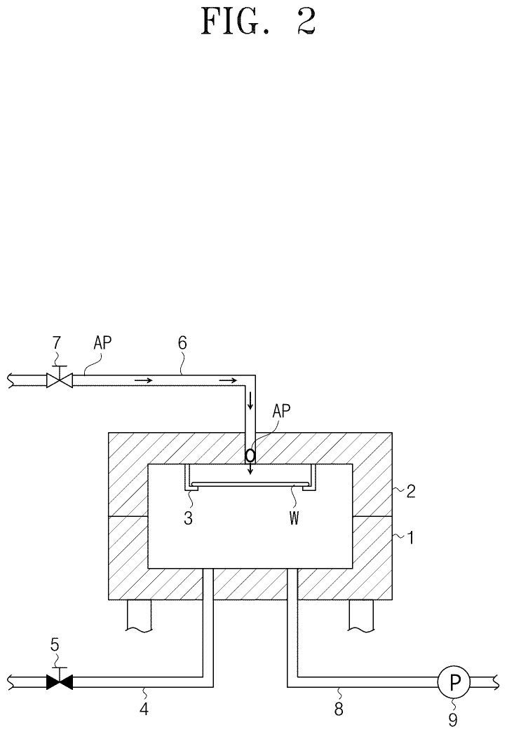

FIG. 3 is a top plan view schematically illustrating a substrate processing apparatus according to an exemplary embodiment of the present invention.

FIG. 4 is a diagram schematically illustrating an exemplary embodiment of a liquid treating chamber of FIG. 3.

FIG. 5 is a diagram schematically illustrating an exemplary embodiment of a drying chamber of FIG. 3.

FIG. 6 is a flow chart illustrating a substrate processing method according to an exemplary embodiment of the present invention.

FIG. 7 is a diagram illustrating a view of the liquid treating chamber performing a liquid treating operation of FIG. 6.

FIG. 8 is a diagram illustrating pressure changes in a processing space of a drying chamber when a drying operation of FIG. 6 is performed.

FIG. 9 is a flow chart illustrating the sequence in which a pressurization operation of FIG. 6 is performed.

FIG. 10 is a diagram illustrating a view of the drying chamber performing a first supply operation of FIG. 9.

FIG. 11 is a diagram illustrating a view of the drying chamber performing an air removal operation of FIG. 9.

FIG. 12 is a diagram illustrating a view of the drying chamber performing a second supply operation of FIG. 9.

FIG. 13 is a diagram illustrating a view in which the drying chamber including an air removal unit performs an air removal operation according to another exemplary embodiment of the present invention.

FIG. 14 is a diagram illustrating a view of a drying chamber including an air removal unit according to another exemplary embodiment of the present invention.

FIG. 15 is a diagram illustrating a view of a drying chamber according to another exemplary embodiment of the present invention.

FIG. 16 is a diagram illustrating a view of a drying chamber according to another exemplary embodiment of the present invention.

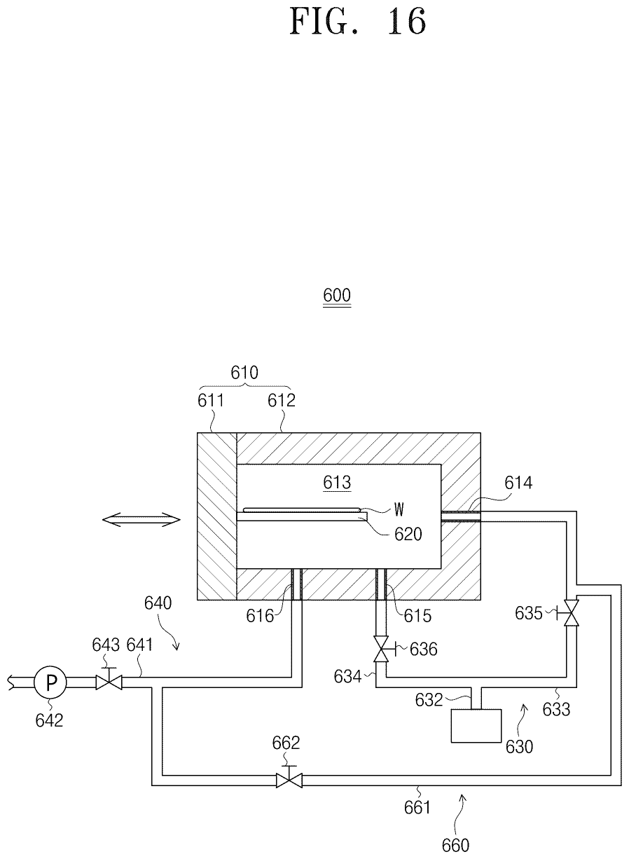

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

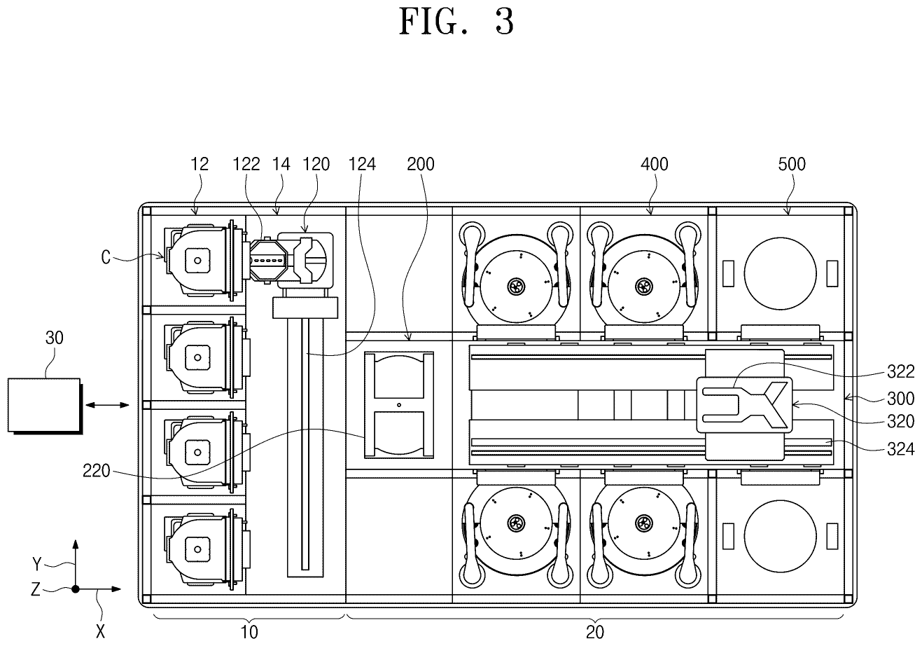

FIG. 3 is a top plan view schematically illustrating a substrate processing apparatus according to an exemplary embodiment of the present invention.

Referring to FIG. 3, the substrate processing apparatus includes an index module 10, a treating module 20, and a controller 30. When viewed from above, the index module 10 and the treating module 20 are disposed along one direction. Hereinafter, the direction in which the index module 10 and the treating module 20 are arranged is referred to as a first direction X, when viewed from above, a direction perpendicular to the first direction X is referred to as a second direction Y, and a direction perpendicular to both the first direction X and the second direction Y is referred to as a third direction Z.

The index module 10 transfers the substrate W from the container C in which the substrate W is accommodated to the treating module 20, and accommodates the substrate W that has been completely treated in the treating module 20 in the container C. A longitudinal direction of the index module 10 is provided in the second direction Y. The index module 10 includes a load port 12 and an index frame 14. Based on the index frame 14, the load port 12 is located at a side opposite to the treating module 20. The container C in which the substrates W are accommodated is placed in the load port 12. A plurality of load ports 12 may be provided, and the plurality of load ports 12 may be disposed along the second direction Y.

As the container C, an airtight container, such as a Front Open Unified Pod (FOUP), may be used. The container C may be placed on the load port 12 by a transport means (not illustrated), such as an overhead transfer, an overhead conveyor, or an automatic guided vehicle, or an operator.

An index robot 120 is provided to the index frame 14. A guide rail 124 of which a longitudinal direction is provided in the second direction Y is provided in the index frame 14, and the index robot 120 may be provided to be movable on the guide rail 124. The index robot 120 includes a hand 122 on which the substrate W is placed, and the hand 122 may be provided to be movable forward and backward directions, rotatable about the third direction Z and movable along the third direction Z. A plurality of hands 122 are provided to be spaced apart in the vertical direction, and the hands 122 may move forward and backward independently of each other.

The treating module 20 includes a buffer unit 200, a transfer chamber 300, a liquid treating chamber 400, and a drying chamber 500. The buffer unit 200 provides a space in which the substrate W loaded into the treating module 20 and the substrate W unloaded from the treating module 20 stay temporarily. The liquid treating chamber 400 performs a liquid treatment process of treating the substrate W with a liquid by supplying a liquid onto the substrate W. The drying chamber 500 performs a drying process of removing the liquid residual on the substrate W. The transfer chamber 300 transfers the substrate W between the buffer unit 200, the liquid treating chamber 400, and the drying chamber 500.

The buffer unit 200 includes a plurality of buffers 220 on which the substrate W is placed. The buffers 220 may be disposed to be spaced apart from each other along the third direction Z. The buffer 220 may be a substrate holder that supports the bottom surface of the substrate W. The buffer 220 may be provided in the form of a support shelf that supports the bottom surface of the substrate W.

A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

A longitudinal direction of the transfer chamber 300 may be provided in the first direction X. The buffer unit 200 may be disposed between the index module 10 and the transfer chamber 300. The liquid treating chamber 400 and the drying chamber 500 may be disposed on the side portion of the transfer chamber 300. The liquid treating chamber 400 and the transfer chamber 300 may be disposed along the second direction Y. The drying chamber 500 and the transfer chamber 300 may be disposed along the second direction Y. The buffer unit 200 may be located at one end of the transfer chamber 300.

According to the example, the liquid treating chambers 400 are disposed on both sides of transfer chamber 300, and the drying chambers 500 are disposed on both sides of the transfer chamber 300, and the liquid treating chambers 400 may be disposed closer to the buffer unit 200 than the drying chambers 500. At one side of the transfer chamber 300, the liquid treating chambers 400 may be provided in an arrangement of A×B (each of A and B is 1 or a natural larger than 1) in the first direction X and the third direction Z. Further, at one side of the transfer chamber 300, the drying chambers 500 may be provided in number of C×D (each of C and D is 1 or a natural number larger than 1) in the first direction 92 and the third direction 96. Unlike the above, only the liquid treating chambers 400 may be provided on one side of the transfer chamber 300, and only the drying chambers 500 may be provided on the other side of the transfer chamber 300.

The transfer chamber 300 includes a transfer robot 320. A guide rail 324 of which a longitudinal direction is provided in the first direction X is provided in the transfer chamber 300, and the transfer robot 320 may be provided to be movable on the guide rail 324. The transfer robot 320 includes a hand 322 on which the substrate W is placed, and the hand 322 may be provided to be movable forward and backward directions, rotatable about the third direction Z and movable along the third direction Z. A plurality of hands 322 are provided to be spaced apart in the vertical direction, and the hands 322 may move forward and backward independently of each other.

The controller 30 may control the substrate processing apparatus. The controller 30 may include a process controller formed of a microprocessor (computer) that executes the control of the substrate processing apparatus, a user interface formed of a keyboard in which an operator performs a command input operation or the like in order to manage the substrate processing apparatus, a display for visualizing and displaying an operation situation of the substrate processing apparatus, and the like, and a storage unit storing a control program for executing the process executed in the substrate processing apparatus under the control of the process controller or a program, that is, a treatment recipe, for executing the process in each component according to various data and treatment conditions. Further, the user interface and the storage unit may be connected to the process controller. The treating recipe may be stored in a storage medium in the storage unit, and the storage medium may be a hard disk, and may also be a portable disk, such as a CD-ROM or a DVD, or a semiconductor memory, such as a flash memory.

The controller 30 may control the configurations of the substrate processing apparatus to perform a substrate processing method described below. For example, the controller 30 may generate control signals to control the opening or closing operation of valves 535, 536, 543, and 552 of the drying chamber 500.

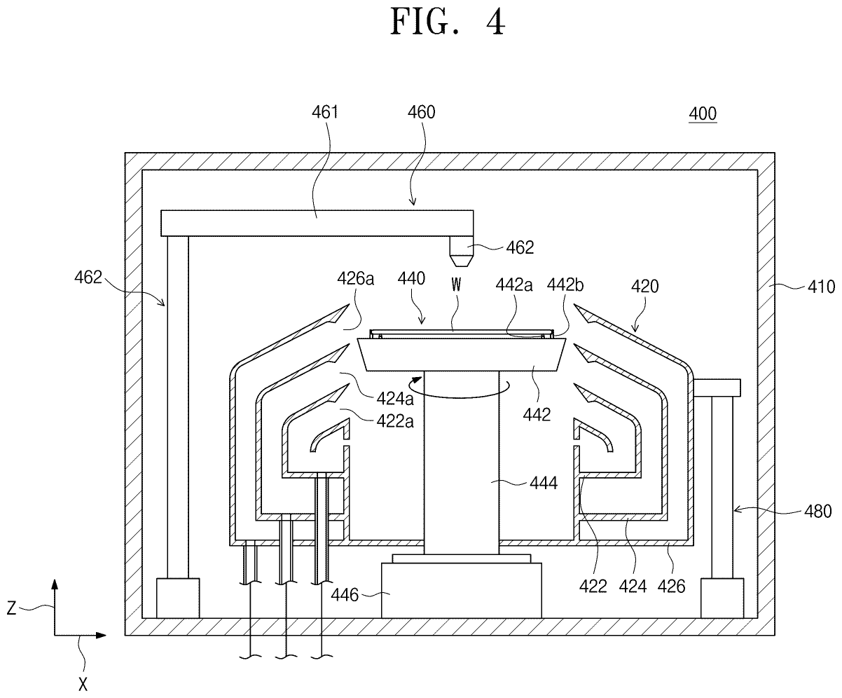

FIG. 4 is a diagram schematically illustrating an exemplary embodiment of a liquid treating chamber of FIG. 3.

Referring to FIG. 4, the liquid treating chamber 400 has a housing 410, a treating container 420, a support unit 440, a liquid supply unit 460, and a lifting unit 480.

The housing 410 may have an interior space where the substrate W is processed. The housing 410 may have a generally hexahedral shape. For example, the housing 410 may have a cuboidal shape. Additionally, the housing 410 may have an opening (not illustrated) through which the substrate W is loaded or unloaded. Additionally, the housing 410 may be equipped with a door (not illustrated) that selectively opens and closes the opening.

The treating container 430 may have a cylindrical shape with an open top. The treating container 420 may provide a processing space where the substrate W is processed. The support unit 440 supports the substrate W in the processing space. The liquid supply unit 460 supplies the treatment solution onto the substrate W supported on the support unit 440. The treatment solution may be provided in a plurality of types and may be supplied sequentially onto the substrate W. The lifting unit 480 adjusts the relative height between the treating container 420 and the substrate W placed on the support unit 440.

In one example, the treating container 420 has a plurality of collection containers 422, 424, and 426. Each of the collection containers 422, 424, and 426 has a collection space of collecting the liquid used for the processing of the substrate. Each of the collection containers 422, 424, and 426 is provided with a shape that surrounds the support unit 440. As the liquid treatment process proceeds, the treatment solution scattered by the rotation of the substrate W enters the collection space through inlets 422a, 424a, and 426a of the respective collection containers 422, 424, and 426. In one example, the treating container 420 has the first collection container 422, the second collection container 424, and the third collection container 426. The first collection container 422 is disposed to surround the support unit 440, the second collection container 424 is disposed to surround the first collection container 422, and the third collection container 426 is disposed to surround the second collection container 424.

The second inlet 424a, which introduces liquid into the second collection container 424, may be positioned above a top side of the first inlet 422a, which introduces liquid into the first collection container 422, and the third inlet 426a, which introduces liquid into the third collection container 426, may be positioned above a top side of the second inlet 424a.

The support unit 440 includes a support plate 442 and a driving shaft 444. An upper surface of the support plate 442 may be provided in a generally circular shape, and may have a diameter larger than a diameter of the substrate W. The edge region of a top surface of the support plate 442 may be provided with a support pin 442a that supports the rear surface of the substrate W. The support pin 442a is provided with a top end protruding from the support plate 442 such that the substrate W is spaced a certain distance from the support plate 442.

A chuck pin 442b is provided to an edge of the top surface of the support plate 442. The chuck pin 442b may be provided at the outer side of the support pin 442a. The chuck pin 442b is provided to protrude upwardly from the support plate 442, and chucks the lateral portion of the substrate W so that the substrate W is not separated from the support unit 440 when the substrate W is rotated. A drive shaft 444 is driven by a driver 446 and is coupled to the center of the lower surface of the support plate 442 and rotates the support plate 442 about its central axis.

The liquid supply unit 460 may supply a treatment solution to the substrate W. The liquid supply unit 460 may include an arm 461, a nozzle 462, and a driver 463. The nozzle 462 may be installed at one end of the bar-shaped arm 461. The driver 463 may be configured in the form of a rotating shaft with the third direction Z as the axis of rotation, and may be coupled to the other end of the arm 461. The driver 463 may rotate the arm 461 axially by rotating in the third direction Z as the axis of rotation. Accordingly, the position of the nozzle 462 installed at one end of the arm 461 may be changed.

The nozzle 462 may supply a treatment solution to the substrate W. The treatment solution may be a chemical, a rinse solution, or an organic solvent. The chemical may be a chemical having the nature of strong acid or strong base. Further, the rinse solution may be pure water. Furthermore, the organic solvent may be isopropyl alcohol (IPA).

While only one nozzle 462 is illustrated in FIG. 4, the liquid supply unit 460 may include a plurality of nozzles 462, each of which may be configured to supply a different type of treatment solution. For example, one of the nozzles 462 may supply a chemical, another of the nozzles 462 may supply a rinse solution, and yet another of the nozzles 462 may supply an organic solvent. Further, the controller 30 may control the liquid supply unit 460 to supply a rinse solution from one of the nozzles 462 to the substrate W, followed by supplying an organic solvent from another one of the nozzles 462. Accordingly, the rinse solution supplied on the substrate W may be replaced with an organic solvent having a small surface tension.

The lifting unit 480 may move the treating container 420 in an upward or downward direction. The relative height between the treating container 420 and the substrate W changes as the treating container 420 is moved up and down. The lifting unit 480 may include a power generating device, such as a motor, pneumatic cylinder, or hydraulic cylinder. The lifting unit 480 may adjust the height of the treating container 420 to differentiate the collection containers 422, 424, and 426 for collecting the treatment solution depending on the type of liquid supplied to the substrate W.

Alternatively, as described above, the treating container 420 may be fixedly installed and the support plate 442 may be configured to be movable in an up and down direction.

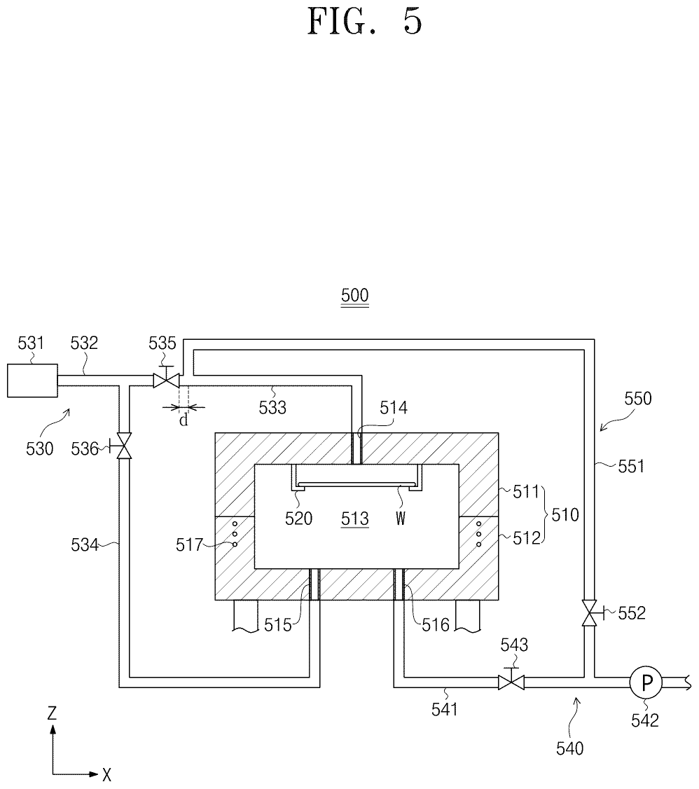

FIG. 5 is a diagram schematically illustrating an exemplary embodiment of the drying chamber of FIG. 3.

Referring to FIG. 5, the drying chamber 500 according to the exemplary embodiment of the present invention may include a body 510, a support member 520, a fluid supply unit 530, a fluid exhaust unit 540, and an air removal unit 550.

The body 510 may provide a processing space 513 where the substrate W is processed. The body 510 may include a first body 511 and a second body 512. At least one of the first body 511 and the second body 512 may have a shape that is recessed in a direction away from the other of the first body 511 and the second body 512. The first body 511 and the second body 512 may be combined with each other to define the processing space 513. The first body 511 and the second body 512 may be formed of a material that can withstand the high pressure conditions of the processing space 513. For example, the first body 511 and the second body 512 may be formed from a material, such as a metal, such as aluminum. The first body 511 may be an upper body positioned at the top, and the second body 512 may be a lower body positioned at the bottom.

A location of at least one of the first body 511 and the second body 512 may be changed by a driver (not illustrated). For example, the position of the first body 511 may be fixed, and the second body 512 may be configured to be movable along the third direction Z. The driver may be any one of an air cylinder, a pneumatic cylinder, a motor, and a magnetic levitation actuator.

The driver may move the second body 512 between an open position and a close position. When the second body 512 is in the open position, the processing space 513 may be open to the outside. When the second body 512 is in the close position, the first body 511 and the second body 512 may be combined with each other to provide the sealed processing space 513.

The first body 511 may be provided with a first supply port 514. The first supply port 514 may be connected to the first fluid supply line 533, which will be described later, to supply treatment fluid to the processing space 513. An outlet of the first supply port 514 faces an upper region of the processing space 513 and may face the upper surface of the substrate W resting on the support member 520. The first supply port 514 may be formed on the first body 511 itself, or may be provided as a separate supply pipe inserted into the first body 511.

The second body 512 may be provided with a second supply port 515. The second supply port 515 may be connected to a second fluid supply line 534, described later, to supply treatment fluid to the processing space 513. The outlet of the second supply port 515 may face a lower region of the processing space 513. Similar to the first supply port 514, the second supply port 515 may be formed in the second body 512 itself, or may be provided as a separate supply pipe inserted into the second body 512.

Additionally, the second body 512 may be provided with an exhaust port 516. The exhaust port 516 may be connected to the exhaust line 541, described later, to exhaust the atmosphere of the processing space 513. The exhaust port 516 may the exhaust treatment fluid, such as carbon dioxide, supplied to the processing space 513 to the outside of the processing space 513 to reduce the pressure in the processing space 513. The exhaust port 516 may be provided in parallel with the second supply port 515. Similar to the first supply port 514 and second supply port 515, the exhaust port 516 may be formed in the second body 512 itself, or may be provided as a separate supply pipe inserted into the second body 512.

In the example described above, the present invention has been described based on the case where the first supply port 514 is provided on the first body 511 and the second supply port 515 and exhaust port 516 are provided on the second body 512 as an example, but the present invention is not limited thereto. For example, the first supply port 514, the second supply port 515, and the exhaust port 516 may all be provided on the first body 511, or all may be provided on the second body 512.

The body 510 may be provided with a heater 517. The heater 517 may be installed while being buried in the interior of the first body 511 and/or the second body 512. The heater 517 may be a resistive heater. Alternatively, the heater 517 may be variously modified to any known device that generates heat. The heater 517 may increase the temperature of the processing space 513. The heater 517 may maintain the temperature of the processing space 513 at a set temperature. Here, the set temperature may be set to a temperature above a critical temperature that allows the state of the treatment fluid to remain supercritical.

The support member 528 may support the substrate W. The support member 520 may be configured to support the substrate W in the processing space 513 provided by the body 510.

The support member 520 may be configured to support a bottom surface of the substrate W. The support member 520 may be configured to support the bottom edge region of the substrate W. The support member 520 may be fixedly installed on the underside of the first body 511. The support members 520 may be provided in pairs. Each support member 520 may extend in a downward direction from the first body 511 toward the second body 512 and may have a laterally bent shape at the end to support the bottom surface of the substrate W.

When the area of contact between the substrate W and the support member 520 is large, the risk of damage, such as scratches, to the bottom surface of the substrate W increases; however, the support member 520 may be configured to support only the edge region of the bottom surface of the substrate W, thereby minimizing the area of contact with the bottom surface of the substrate W.

The fluid supply unit 530 may supply the treatment fluid to the processing space 513. The treatment fluid may be drying gas that removes any residual treatment solution on the substrate W. For example, the treatment fluid may be carbon dioxide gas. The treatment fluid may also be converted to a supercritical state and supplied to the processing space 513. Alternatively, the treatment fluid may be supplied to the processing space 513 in a gaseous state and phase converted to the supercritical state in the processing space 513.

The fluid supply unit 530 may include a fluid supply source 531, a main supply line 532, a first fluid supply line 533, a second fluid supply line 534, a first supply valve 535, and a second supply valve 536.

The supply lines 532, 533, and 534 may be equipped with line heaters (not illustrated) to heat the treatment fluid flowing in the supply lines 532, 533, and 534.

The fluid supply source 531 may store and supply treatment fluid. The fluid supply source 531 may be a fluid storage tank capable of storing and supplying the treatment fluid. The fluid supply source 531 may be configured to store and supply carbon dioxide.

The fluid supply source 531 may be connected to one end of the main supply line 532. The other end of the main supply line 532 may be branched into a first fluid supply line 533 and a second fluid supply line 534. The first fluid supply line 533 may be connected to the first supply port 514 described above. The second fluid supply line 534 may be connected to the second supply port 515. The first fluid supply line 533 may be configured to supply treatment fluid to an upper region of the processing space 513, and the second fluid supply line 534 may be configured to supply treatment fluid to a lower region of the processing space 513.

The first supply valve 535 may be installed in the first fluid supply line 533. The first supply valve 535 may be provided as an auto valve that receives a control signal from the controller 30 to allow or block the flow of the treatment fluid in the first fluid supply line 533.

Similarly, the second fluid supply line 534 may be provided with the second supply valve 536. The second supply valve 536 may be provided as an auto valve that receives a control signal from the controller 30 to allow or block the flow of treatment fluid in the second fluid supply line 534.

The fluid exhaust unit 540 may control the atmosphere of the processing space 513. The fluid exhaust unit 540 may exhaust the treatment fluid supplied to the processing space 513 to the outside of the drying chamber 500. The fluid exhaust unit 540 may include a fluid exhaust line 541, an exhaust device 542, and an exhaust valve 543.

The fluid exhaust line 541 may be connected with the exhaust port 516 described above. The exhaust valve 543 may be installed in the fluid exhaust line 541, and the exhaust valve 543 may be provided as an auto valve that receives a control signal from the controller 30 to allow or block the flow of the treatment fluid in the exhaust line 541.

An exhaust device 542 may be coupled to the exhaust line 541. The exhaust device 542 may be a pressure reducing device that depressurizes the processing space 513. For example, the exhaust device 542 may be a pump. However, without limitation, the exhaust device 542 may be variously modified to any known device that is capable of providing depressurization to the processing space 513 through the exhaust line 541 and the exhaust port 516.

The air removal unit 550 may be configured to remove air of the processing space 513 that may be introduced from the fluid supply unit 530, from the fluid supply unit 530. For example, the air removal line 551 may be configured to remove treatment fluid that may be introduced from the processing space 513 from the first fluid supply line 533. The air removal unit 550 may include the air removal line 551, and an air removal valve 552.

One end of the air removal line 551 may be connected to the first fluid supply line 533 in a lower stream than the first supply valve 535, which is installed in the first fluid supply line 533. Further, the other end of the air removal line 551 may also be connected to the exhaust line 541 in a lower stream than the exhaust valve 543, which is installed in the exhaust line 541.

The air removal line 551 may be connected to the first fluid supply line 533 at a location very close to the first supply valve 535. The air removal line 551 may be connected to the first fluid supply line 533 at a location within 200 mm of the first supply valve 535. For example, the distance “d” from the side portion of the first supply valve 535 to the connection point of the first fluid supply line 533 to which the air removal line 551 is connected may be between 0 and 200 mm, more preferably between 0 and 100 mm. This is because when “d” is greater than 200 mm, it is difficult to remove an air pocket described later from the first fluid supply line 533.

The air removal valve 552 may be installed in the air removal line 551. The air removal valve 552 may be provided as an auto valve that receives a control signal from the controller 30 to allow or block the flow of air or treatment fluid in the air removal line 551.

FIG. 5 illustrates the present invention based on the case where the location of the air removal valve 552 is closer to the exhaust valve 543 than the first supply valve 535 as an example, but the present invention is not limited thereto. For example, the first supply valve 535 may be positioned closer to the first supply valve 535 than the exhaust valve 543. Additionally, similar to the first supply valve 535, the air removal valve 552 may be installed within 200 mm of the connection point where the air removal line 551 and the first fluid supply line 533 are connect to each other.

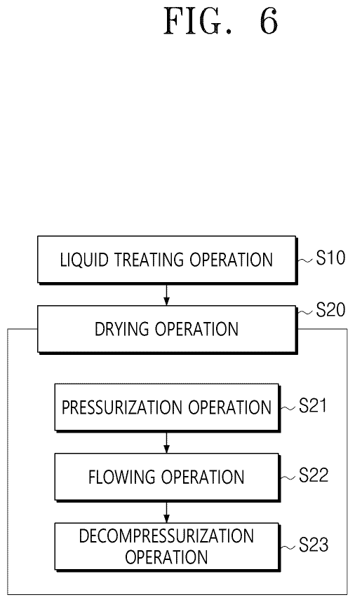

FIG. 6 is a flow chart illustrating a substrate processing method according to an exemplary embodiment of the present invention.

Referring to FIGS. 3 and 6, a substrate processing method according to an exemplary embodiment of the present invention may include a liquid treating operation S10 and a drying operation S20. The liquid treating operation S10 and the drying operation S20 may be performed sequentially, and the liquid treating operation S10 may be performed in the liquid treating chamber 400 described above and the drying operation S20 may be performed in the drying chamber 500 described above.

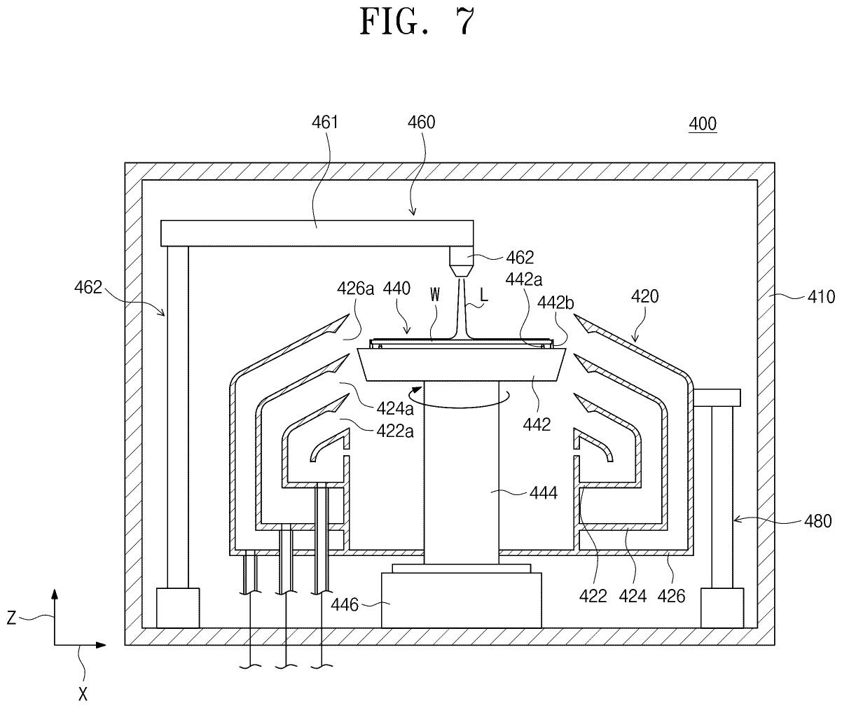

FIG. 7 is a diagram illustrating a view of the liquid treating chamber performing the liquid treating operation of FIG. 6.

Referring to FIGS. 4, 6, and 7, in the liquid treating operation S10, the support unit 440 rotates the substrate W, and the liquid supply unit 460 supplies a treatment solution L to the rotating substrate W to liquid treat the substrate W. The treatment solution L supplied by the liquid supply unit 460 may be a cleaning liquid for cleaning the substrate, for example, a rinse liquid such as pure water or an organic solvent such as IPA. The liquid treating operation S10 may include supplying a rinse liquid to the substrate W to clean the substrate W, and then supplying an organic solvent to the substrate W to replace any residual rinse liquid on the substrate W with the organic solvent.

The substrate W on which the liquid treatment has been performed may be unloaded from the liquid treating chamber 400 by the transfer robot 320 and loaded into the drying chamber 500. On the substrate W loaded into the drying chamber 500, a liquid film may be formed by the treatment solution supplied from the liquid treating chamber 400. The liquid film may be a liquid film formed by the organic solvent described above.

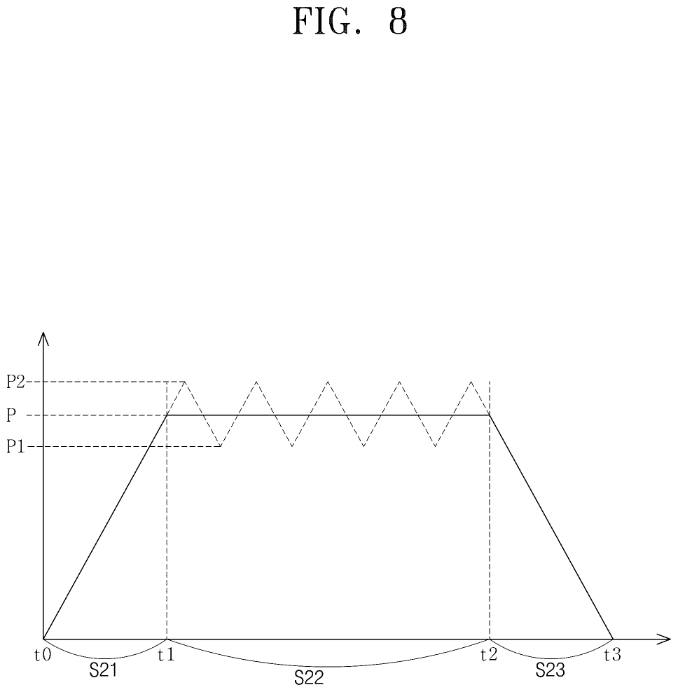

FIG. 8 is a diagram illustrating pressure changes in the processing space of the drying chamber when the drying operation of FIG. 6 is performed.

Referring to FIGS. 5, 6, and 8, the drying operation S20 may include a pressurization operation S21, a flowing operation S22, and a decompression operation S22.

The pressurization operation S21 may be performed after the substrate W is loaded into the drying chamber 500. The pressurization operation S21 may include supplying treatment fluid to the processing space 513 to increase the pressure in the processing space 513 to a set pressure P. The set pressure P may be a pressure greater than a threshold pressure at which the treatment fluid supplied to the processing space 513 remains supercritical or may phase change from a gaseous state to a supercritical state. The pressurization operation S21 may be performed by the exhaust valve 543 being shut off, the first supply valve 535 and/or the second supply valve 536 being opened to supply treatment fluid to the processing space 513.

The flowing operation S22 may include flowing the treatment fluid in the processing space 513 to remove any residual treatment solution on the substrate W.

In the flowing operation S22, the pressure in the processing space 513 may be maintained constant at the set pressure P by equating the supply flow rate per unit time of the treatment fluid supplied into the processing space 513 with the exhaust flow rate per unit time of the treatment fluid exhausted from the processing space 513.

Alternatively, in the flowing operation S22, the supply of the treatment fluid and the exhaust of the treatment fluid are alternately and repeatedly performed to flow the treatment fluid by pulsing the pressure in the processing space 513 between a first pressure P1 and a second pressure P2. In this case, both the first pressure P1 and the second pressure P2 may be treater than the threshold pressure at which the treatment fluid supplied to the processing space 513 remains supercritical or may phase change from a gaseous state to a supercritical state.

In the flowing operation S22, pressure control within the processing space 513 may be implemented by opening or closing the first supply valve 535, the second supply valve 536, and the exhaust valve 543.

The depressurization operation S23 may be an operation to depressurize the processing space 513 in a high pressure state. In the depressurization operation S23, the pressure of the processing space 513 may be reduced to change the pressure of the processing space 513 to equal or similar to the normal pressure. After the end of the depressurization operation S23, the second body 512 may descend, the processing space 513 may open, and the substrate W that was provided in the processing space 513 may be unloaded from the drying chamber 500.

In the following, the pressurization operation S21 according to the exemplary embodiment of the present invention will be described in more detail. The pressurization operation S21 may include pressurizing the pressure in the processing space 513 provided by the body 510 from normal pressure to the set pressure P, and during this process, air introduced into the first fluid supply line 533 may be removed from the first fluid supply line 533.

The pressurization operation S21 may include a first supply operation S21A, an air removal operation S21B, and a second supply operation S21C. The first supply operation S21A and the second supply operation S21C may be performed sequentially. Further, the first supply operation S21A may begin before the air removal operation S21B, but the timing when the first supply operation S21A and the air removal operation S21B are performed may overlap at least partially. Further, the second supply operation S21C may be performed after the end of the air removal operation S21B.

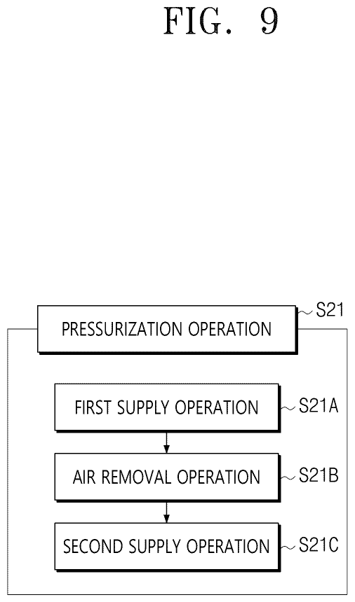

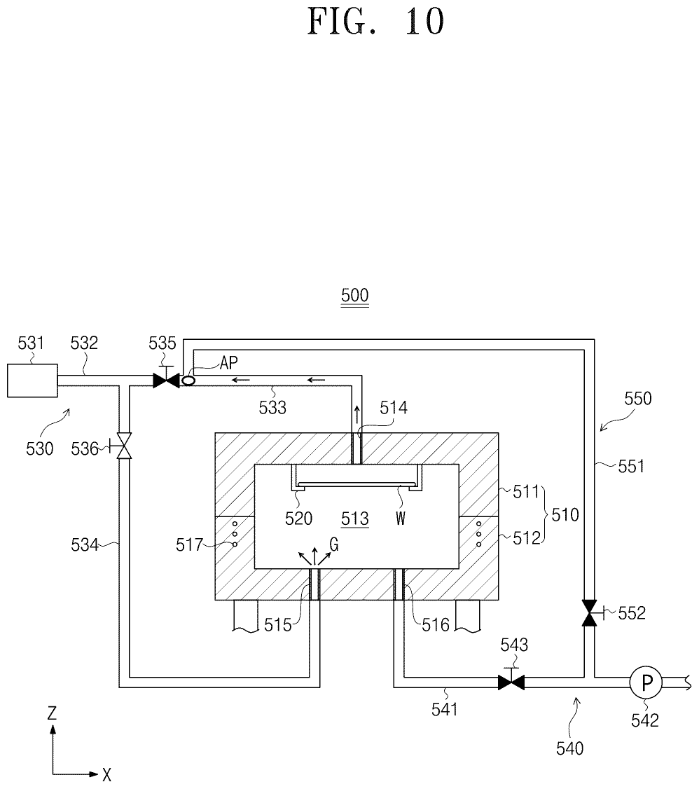

FIG. 10 is a diagram illustrating a view of the drying chamber performing the first supply operation of FIG. 9.

Referring to FIGS. 9 and 10, in the first supply operation S21A, the second supply valve 536 may be open, and the first supply valve 535 and the exhaust valve 543 may be closed. Additionally, the air removal valve 552 may be closed. In the first supply operation S21, the second fluid supply line 534 may supply treatment fluid G to the processing space 513 through the second supply port 515.

Since in the state where the processing space 513 is not pressurized, when the treatment fluid G is supplied to the substrate W through the first supply port 514, the treatment fluid G supplied to the processing space 513 may not phase change to a supercritical state, or may be difficult to maintain a supercritical state, the processing space 513 may be pressurized by first supplying the treatment fluid G to a lower region of the processing space 513.

The treatment fluid G supplied in the first supply operation S21A may push the air residing in the processing space 513 in a direction toward the first supply port 514. The air of the processing space 513 that has been pushed toward the first supply port 514 by the treatment fluid G supplied in the first supply operation S21A may be introduced to the first fluid supply line 533 to form an air pocket AP. Additionally, in some cases, the air may also be introduced directly into the air removal line 551 that is connected to the first fluid supply line 533 without forming the air pocket AP.

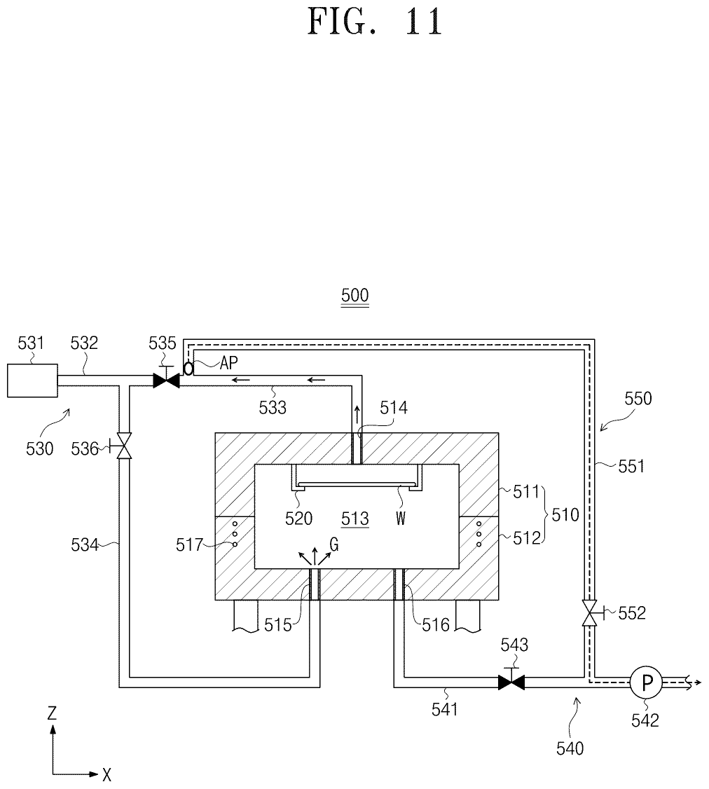

FIG. 11 is a diagram illustrating a view of the drying chamber performing the air removal operation of FIG. 9.

Referring to FIGS. 9 and 11, the air removal operation S21B may include removing air introduced to the first fluid supply line 533 from the processing space 513 by the treatment fluid G supplied in the first supply operation S21A from the first fluid supply line 533. In the air removal operation S21B, the first supply valve 535 and the exhaust valve 543 may be closed, and the second supply valve 536 and the air removal valve 552 may be open. With the second supply valve 536 open, the treatment fluid G may continue to be supplied from the second supply port 515, and the air introduced into the first fluid supply line 533 may flow through the air removal line 551 toward the exhaust line 541. Upon reaching the exhaust line 541, the air may be discharged to the outside of the drying chamber 500 through the exhaust line 541.

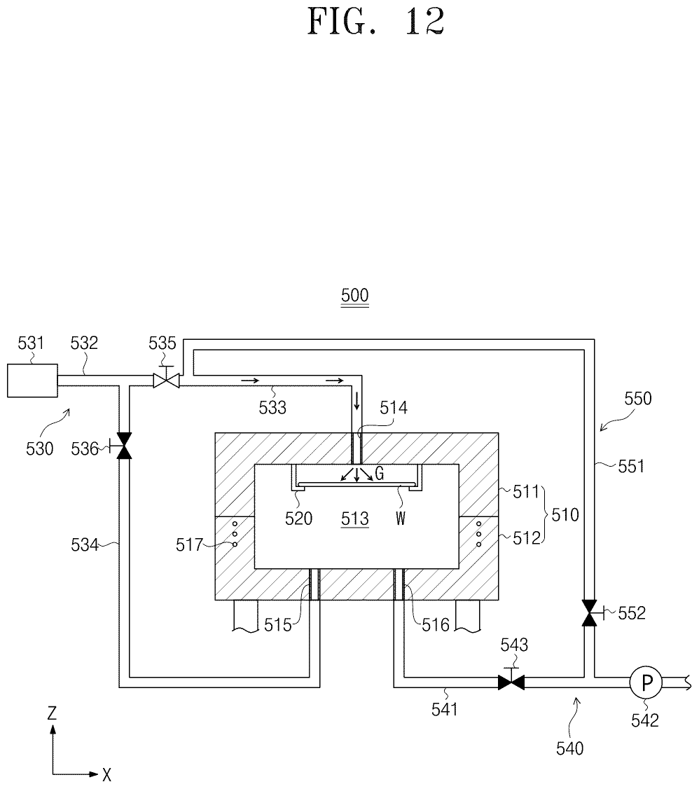

FIG. 12 is a diagram illustrating a view of the drying chamber performing the second supply operation of FIG. 9.

Referring to FIGS. 9 and 12, once the air removal operation S21B is performed to remove the air introduced into the first fluid supply line 533, the second supply operation S21C may be performed.

Before the second supply operation S21C is performed, the air introduced into the first fluid supply line 533 is removed, thereby minimizing air being delivered to the substrate W through the first fluid supply line 533 in the second supply operation S21C and causing defects in the substrate W.

By sequentially going through the first supply operation S21A, the air removal operation S21B, and the second supply operation S21C, the pressure in the processing space 513 may rise from normal pressure to the set pressure P.

When the processing space 513 is pressurized, when any one of the plurality of fluid supply lines 533 and 534 is supplied with the treatment fluid G, air may be introduced into the other of the plurality of fluid supply lines 533 and 534. The introduced air may be compressed to form the air pocket AP, which may be delivered to the substrate W when the other of the plurality of fluid supply lines 533 and 534 is supplied with the treatment fluid G.

According to the exemplary embodiment of the present invention, the air removal line 551 is connected to a location adjacent to the supply valve 535 installed in the other of the plurality of fluid supply lines 533 and 534, and air is removed through the air removal line 551, thereby minimizing the risk of defects on the substrate W.

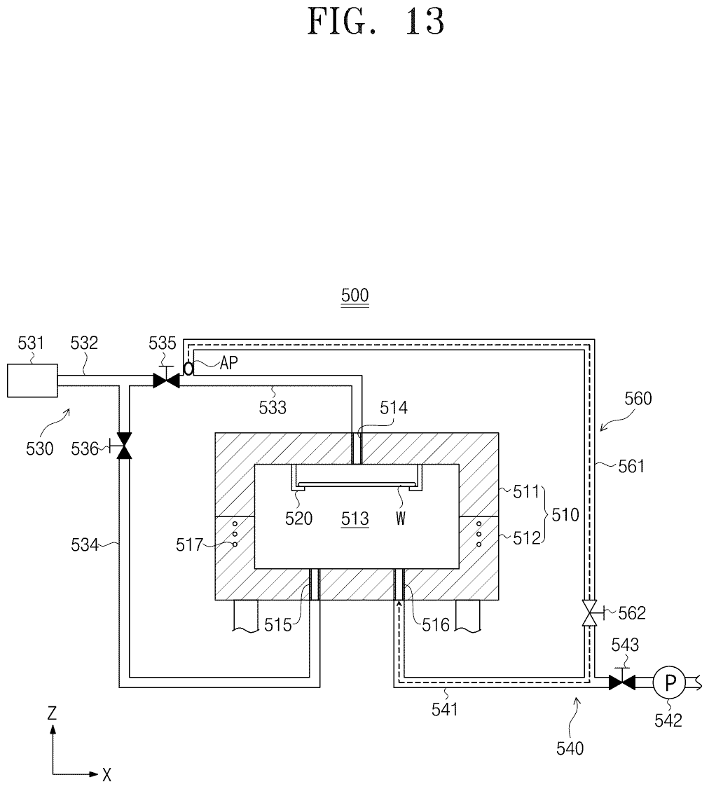

FIG. 13 is a diagram illustrating a view in which the drying chamber including the air removal unit performs an air removal operation according to another exemplary embodiment of the present invention.

The air removal line 551 is connected to the exhaust line 541 in a lower stream than the exhaust valve 543 and functions as an exhaust line to discharge air to the outside of the drying chamber 500. The air removal unit 560 according to another exemplary embodiment may include an air removal line 561 and an air removal valve 552. The air removal line 561 may be connected to the exhaust line 541 in the upper stream than the exhaust valve 543 and function as a circulation line. The air removal line 561 may remove air from the first fluid supply line 533 and recirculate the air through the exhaust line 541 to the processing space 513.

In this way, even when air is not discharged from the drying chamber 500 and recirculated into the processing space 513, defects on the substrate W may be minimized. First, even when air is introduced into the first fluid supply line 533, the air is likely to be circulated by the air removal line 561, so that a possibility that the air pocket Aps is not formed is high. Even though the air pocket AP is formed, when the air is circulated through the air removal line 561 and is introduced into the processing space 513, which is very large in volume relative to the lines, the air may be diluted by the large amount of treatment fluid G supplied to the processing space 513 and have very little impact on the substrate W.

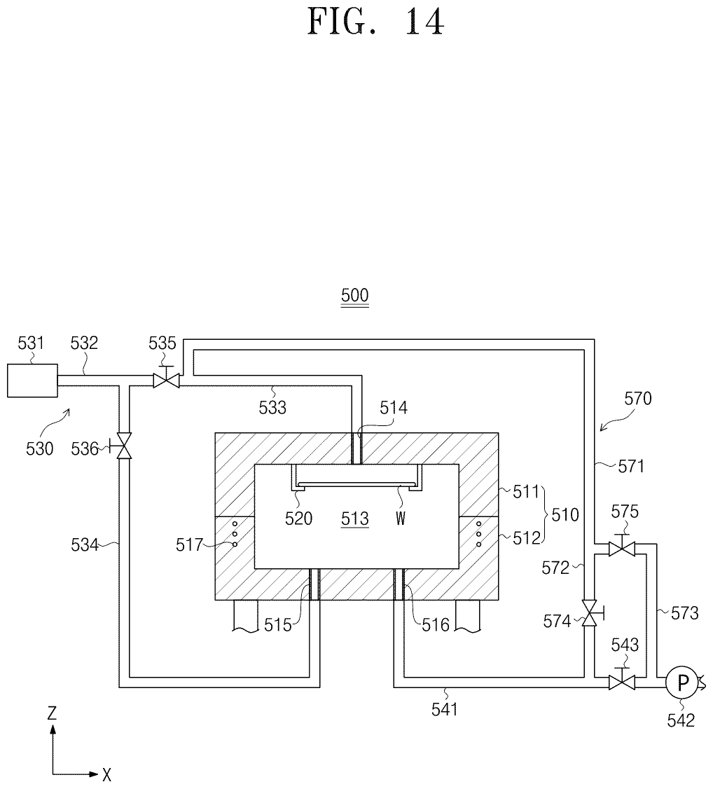

FIG. 14 is a diagram illustrating a view of a drying chamber including an air removal unit according to another exemplary embodiment of the present invention.

Referring to FIG. 14, an air removal unit 570 according to another exemplary embodiment of the present invention may include a main air removal line 571, a circulation line 572, a discharge line 573, a circulation valve 574, and a discharge valve 575.

One end of the main air removal line 571 may be connected to the first fluid supply line 533, and the other end may be branched into the circulation line 572 and the discharge line 573. In other words, the air removal unit 570 may discharge the air introduced into the first fluid supply line 533 to the outside of the drying chamber 500, or optionally circulate the air to the processing space 513.

Additionally, to allow the user to more reliably remove the air introduced into the first fluid supply line 533, the treatment fluid G supplied by the second supply port 515 may be circulated through the circulation line 572 after the air has been pre-discharged through the discharge line 573 to minimize the risk of air-induced defects on the substrate W.

The example described above illustrates, but is not limited to, the body 510 including the first body 511 that is the upper body and the second body 512 that is the lower body.

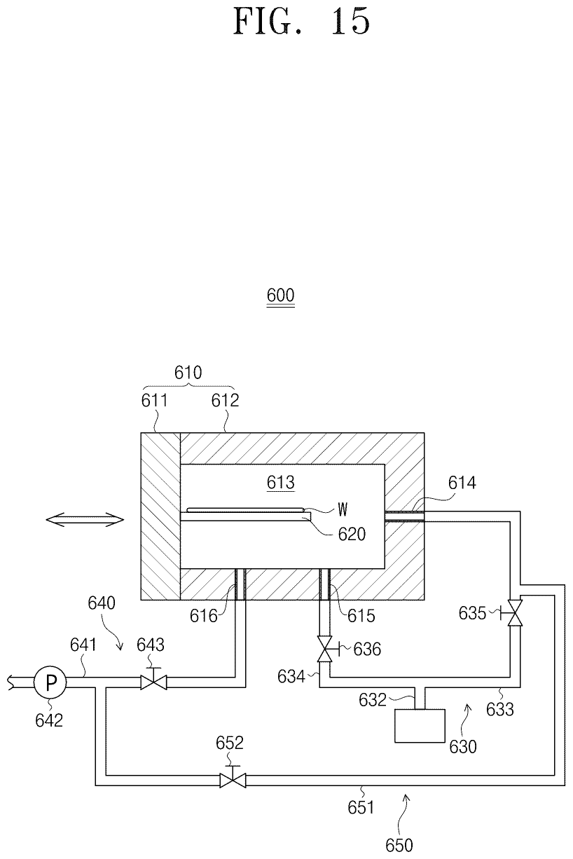

FIG. 15 is a diagram illustrating a view of a drying chamber according to another exemplary embodiment of the present invention. A drying chamber 600 according to another exemplary embodiment may include a body 610, a support member 620, a fluid supply unit 630, a fluid exhaust unit 640, and an air removal unit 650.

The body 610 may include a first body 611, which may be a door configured to be laterally movable, and a second body 612, which may have a barrel shape with an open side. The support member 620 may be installed on the first body 611 to support the bottom surface of the substrate W. The first body 611 may be laterally moved to be combined with the second body 612. The first and second bodies 611 and 612 may be combined with each other to provide a processing space 613.

The fluid supply unit 630 may include a main supply line 632, a first fluid supply line 633, a second fluid supply line 634, a first supply valve 635, and a second supply valve 636, and the first fluid supply line 633 may be connected to a first supply port 614 provided on the second body 612, and the second fluid supply line 634 may be connected to a second supply port 615 provided on the second body 612. The configurations of the fluid supply unit 630 perform the same or similar functions as the fluid supply unit 530 described above, and therefore will not be described repeatedly.

The fluid exhaust unit 640 may include an exhaust line 641, an exhaust device 642, and an exhaust valve 643, and the exhaust line 633 may be connected to an exhaust port 616 provided in the second body 612. The configurations of the fluid exhaust unit 640 perform the same or similar functions as the fluid exhaust unit 540 described above and will not be described repeatedly. The air removal unit 650 may include an air removal line 651 and an air removal valve 652, and one end of the air removal line 651 may be connected to the first fluid supply line 633 at a location very close to the first supply valve 635 (for example, a location within 200 mm from the first supply valve 635). Additionally, the other end of the air removal line 651 may be connected to the exhaust line 641 in a lower stream than the exhaust valve 643. In this case, the air removal line 651 may function as an exhaust line.

However, without limitation, the other end of the air removal line 651 may be connected to the exhaust line 641 in the upper stream than the exhaust valve 643. In this case, the air removal line 651 may function as a circulation line.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even if not specifically illustrated or described. The modifications are not to be considered as departing from the spirit and scope of the disclosure, and all such modifications that would be obvious to one of ordinary skill in the art are intended to be included within the scope of the accompanying claims.

1. An apparatus for processing a substrate, the apparatus comprising:
a body providing a processing space;
a first fluid supply line connected to the body and supplying treatment fluid to the processing space;
a second fluid supply line connected to the body at a location different from the first fluid supply line and supplying treatment fluid to the processing space;
a first supply valve installed in the first fluid supply line; and
an air removal line having one end connected to the first fluid supply line in a lower stream than the first supply valve to allow air in the processing space that is introduced into the first fluid supply line to be removed from the first fluid supply line when the second fluid supply line supplies treatment fluid to the processing space.

2. The apparatus of claim 1, further comprising:
an exhaust line for exhausting atmosphere of the processing space,
wherein the other end of the air removal line is connected to the exhaust line.

3. The apparatus of claim 2, further comprising:
an exhaust line installed in the exhaust line,
wherein to allow air introduced into the air removal line to be discharged from the processing space, the other end of the air removal line is connected to the exhaust line in a lower stream than the exhaust valve.

4. The apparatus of claim 2, further comprising:
an exhaust line installed in the exhaust line,
wherein to allow air introduced into the air removal line to be circulated to the processing space, the other end of the air removal line is connected to the exhaust line in an upper stream than the exhaust valve.

5. The apparatus of claim 2, further comprising:
an exhaust line installed in the exhaust line,
wherein the air removal line includes:
a main removal line connected with the first fluid supply line;
a circulation line branched from the main removal line and connected to an upper stream than the exhaust valve; and
a discharge line branched from the main removal line to be connected to a lower stream than the exhaust valve.

6. The apparatus of claim 1, wherein the air removal line is connected to the first fluid supply line within 200 mm from the first supply valve.

7. The apparatus of claim 1, wherein the body is provided with a first supply port connected with the first fluid supply line, and a second supply port connected with the second fluid supply line, and
an outlet of the first supply port and an outlet of the second supply port face each other.

8. The apparatus of claim 1, further comprising:
an air removal valve installed in the air removal line;
a second supply valve installed in the second fluid supply line; and
a controller configured to control an operation of the first supply valve, the second supply valve, and the air removal valve,
wherein the controller configured to generate signals for performing:
an operation of closing the first supply valve and opening the second supply valve to allow the treatment fluid to be supplied to the processing space through the second fluid supply line; and
an operation of opening the air removal valve to allow air in the processing space that is introduced into the first fluid supply line to be introduced into the air removal line.

9. The apparatus of claim 8, wherein the controller configured to generate a control signal to perform an operation of opening the first supply valve to allow the treatment fluid to be supplied to the processing space through the first fluid supply line after air is introduced into the air removal line.

10.-17. (canceled)

18. An apparatus for processing a substrate, the apparatus comprising:
a body providing a processing space;
a fluid supply unit for supplying treatment fluid to the processing space;
an exhaust unit for exhausting atmosphere of the processing space; and
an air removal line for removing air introduced into the fluid supply unit,
wherein the fluid supply unit includes:
a first fluid supply line for supplying treatment fluid to a first region of the processing space;
a second fluid supply line for supplying treatment fluid to a second region that is different from the first region of the processing space;
a first supply valve installed in the first fluid supply line; and
a second supply valve installed in the second fluid supply line, and
the exhaust unit includes:
an exhaust line connected to the body; an exhaust valve installed on the exhaust line; and
an exhaust device for exhausting atmosphere of the processing space through the exhaust line, and
the air removal line has one end that is connected to the first fluid supply line at a location within 200 mm from the first supply valve and the other end connected to the exhaust line.

19. The apparatus of claim 18, further comprising:
an air removal valve installed in the air removal line; and
a controller configured to control an operation of the first supply valve, the second supply valve, and the air removal valve,
wherein the controller configured to generate signals for performing:
an operation of closing the first supply valve and opening the second supply valve to allow the treatment fluid to be supplied to the processing space through the second fluid supply line; and
an operation of opening the air removal valve to allow air in the processing space that is introduced into the first fluid supply line to be introduced into the air removal line.

20. The apparatus of claim 19, wherein the controller configured to control generate a control signal to perform an operation to open the first supply valve to allow the treatment fluid to be supplied to the processing space through the first fluid supply line after air is introduced into the air removal line.
